(19) United States
(12) Patent Application Publication
(10) Pub. No.: US 2025/0176243 A1
(43) Pub. Date: May 29, 2025

(54) GATE STRUCTURE, SEMICONDUCTOR DEVICE AND PREPARATION METHOD FOR SEMICONDUCTOR DEVICE

(71) Applicant: Dynax Semiconductor, Inc., Suzhou (CN)

(72) Inventors: Hongtu QIAN, Suzhou (CN); Qingzhao GU, Suzhou (CN); Yi PEI, Suzhou (CN); Naiqian ZHANG, Suzhou (CN)

(73) Assignee: Dynax Semiconductor, Inc., Suzhou (CN)

(21) Appl. No.: 19/037,181

(22) Filed: Jan. 25, 2025

Related U.S. Application Data
(63) Continuation of application No. PCT/CN2023/114844, filed on Aug. 25, 2023.

(30) Foreign Application Priority Data
Aug. 25, 2022 (CN) 202211027929.4
Aug. 25, 2022 (CN) 202222253480.5

(51) Int. Cl. H10D 64/00; H10D 64/01; H10D 64/27

(52) U.S. Cl. CPC H10D 64/112; H10D 64/01; H10D 64/519

(57) ABSTRACT

A gate structure includes a gate portion and a field plate portion, a projection of a tail end point on a lower surface of the lower field plate sub-portion is located on a side, close to the first plane, of a projection of a start end point on a lower surface of an upper field plate sub-portion, and the start end point on the lower surface of the upper field plate sub-portion is coincidence with an end point where an upper surface of the lower field plate sub-portion is connected to the lower surface of the upper field plate sub-portion. In the gate structure of the present disclosure, the two adjacent field plate sub-portions are non-perpendicularly connected to each other, thereby achieving an effect of optimizing electric field distribution, thus improving reliability and stability of semiconductor devices.

### CROSS-REFERENCE TO RELATED APPLICATIONS

This application is a continuation of International Application No. PCT/CN2023/114844, filed on Aug. 25, 2023, which claims priority to Chinese Patent Application No. 202211027929.4 and Chinese Patent Application No. 202222253480.5, both filed on Aug. 25, 2022. The disclosures of the aforementioned applications are hereby incorporated by reference in their entireties.

### TECHNICAL FIELD

The present disclosure relates to the field of semiconductor technologies, and in particular, to a gate structure, a semiconductor device and a preparation method for the semiconductor device.

### BACKGROUND

In the field of 5G communications, there are high requirements on bandwidth and high-frequency characteristics of semiconductor Radio Frequency (RF) devices, while a design and a process flow of a gate structure are closely related to frequency characteristics of semiconductor devices, which directly affects operating frequency of semiconductor devices. In addition, the design of the gate structure also has a significant impact on an electric field of the devices, and is extremely important to maintain reliability and stability of the semiconductor devices.

### SUMMARY

The present disclosure provides a gate structure, a semiconductor device and a preparation method for the semiconductor device, so as to further improve bandwidth and high-frequency characteristics of semiconductor devices, as well as reliability and stability of semiconductor devices.

According to a first aspect of the present disclosure, a gate structure is provided, including a gate portion and a field plate portion, the field plate portion includes at least two field plate sub-portions; in two adjacent field plate sub-portions, a field plate sub-portion away from the gate portion is an upper field plate sub-portion, and a field plate sub-portion close to the gate portion is a lower field plate sub-portion; in a direction from the gate portion to the field plate portion, the gate portion and the field plate portion are each divided into two parts by a first plane, and in either of the two parts, on a plane where a bottom surface, away from the lower field plate sub-portion, of the gate portion is located, a projection of a tail end point on a lower surface of the lower field plate sub-portion is located on a side, close to the first plane, of a projection of a start end point on a lower surface of the upper field plate sub-portion, and the start end point on the lower surface of the upper field plate sub-portion is coincidence with an end point where an upper surface of the lower field plate sub-portion is connected to the lower surface of the upper field plate sub-portion; and an upper surface of one field plate sub-portion is a surface away from the gate portion, and a lower surface of one field plate sub-portion is a surface close to the gate portion; and on a surface, on a same side, of a same field plate sub-portion, a start end point is an end point, close to the first plane, of the surface of the field plate sub-portion, and a tail end point is an end point, away from the first plane, of the surface of the field plate sub-portion.

According to a second aspect of the present disclosure, a gate structure is provided, including a gate portion and a field plate portion; in a direction from the gate portion to the field plate portion, the gate portion and the field plate portion are each divided into two parts by a first plane, and in either of the two parts, the gate portion includes a bottom surface away from the field plate portion and a first side surface connected to the bottom surface, and on a plane where the bottom surface of the gate portion is located, a projection of an end point where the gate portion is connected to the field plate portion is located on a side, away from the first plane, of a projection of an end point where the bottom surface is connected to the first side surface; in the two parts, a distance relationship between the end point where the gate portion is connected to the field plate portion and the end point where the bottom surface is connected to the first side surface is: M0<L0 and M0′<L0; and on the plane where the bottom surface of the gate portion is located, the M0 represents a distance, on a side of the first plane, between the projection of the end point where the gate portion is connected to the field plate portion and the projection of the end point where the bottom surface is connected to the first side surface, and the M0′ represents a distance, on another side of the first plane, between the projection of the end point where the gate portion is connected to the field plate portion and the projection of the end point where the bottom surface is connected to the first side surface; and the L0 represents a distance between the projection of the end point, on the side of the first plane, where the bottom surface is connected to the first side surface and the projection of the end point, on the another side of the first plane, where the bottom surface is connected to the first side surface.

According to a third aspect of the present disclosure, a semiconductor device is provided, including: a substrate; a semiconductor layer formed on a side of the substrate; a passivation layer formed on a side, away from the substrate, of the semiconductor layer; and the gate structure according to the first aspect or the second aspect, the gate structure being formed on a side, away from the substrate, of the passivation layer, and a field plate portion being located on a side, away from the semiconductor layer, of a gate portion.

According to a fourth aspect of the present disclosure, a preparation method for a semiconductor device is provided, which is applied for preparing the semiconductor device in the third aspect. The preparation method includes: forming a semiconductor layer on a side of a substrate; forming a passivation layer on a side, away from the substrate, of the semiconductor layer; performing a first photoetch on the passivation layer using a first photoresist to etch the passivation layer, so as to form a first layer of an opening in the passivation layer, in a direction perpendicular to a direction from the substrate to the passivation layer, an opening size of the first photoresist before etching being L1+L1′+L0+M0+M0′, and an opening size of the first photoresist after etching being L1+L1′+L0+M0+M0′+M1+M1′, and in the direction from the substrate to the passivation layer, a size of the first layer of an opening being D1; performing, based on the first layer of an opening, a second photoetch on the passivation layer using a second photoresist to etch the passivation layer, so as to form a second layer of an opening below the first layer of an opening in the passivation layer, in the direction perpendicular to the direction from the substrate to the passivation layer, an opening size of the second photoresist before etching being L0, and an opening size of the second photoresist after etching being L0+M0+M0′, and in the direction from the substrate to the passivation layer, a size of the second layer of an opening being D0, and the second layer of an opening exposing the semiconductor layer; and depositing a gate structure, so as to form a gate portion and a field plate portion, the gate portion fully filling the second layer of an opening, and the field plate portion covering the gate portion and fully filling the first layer of an opening.

According to a fifth aspect of the present disclosure, a preparation method for a semiconductor device is provided, which is applied for preparing the semiconductor device in the third aspect. The preparation method includes: forming a semiconductor layer on a side of a substrate; forming a passivation layer on a side, away from the substrate, of the semiconductor layer; performing a first photoetch on the passivation layer using a photoresist to etch the passivation layer, so as to form a first layer of an opening in the passivation layer, in a direction perpendicular to a direction from the substrate to the passivation layer, an opening size of the photoresist before etching being L0, and an opening size of the photoresist after etching being L0+M0+M0′, and in the direction from the substrate to the passivation layer, a size of the first layer of an opening being D0; widening, by selective etching, the photoresist after etching, in the direction perpendicular to the direction from the substrate to the passivation layer, an opening size of the photoresist after widening being L1+L1′+L0+M0+M0′; performing, based on the first layer of an opening, a second photoetch on the passivation layer using the photoresist after widening to etch the passivation layer, so as to descend the first layer of an opening in a direction towards the substrate integrally, thereby forming a second layer of an opening above the first layer of an opening in the passivation layer, in the direction perpendicular to the direction from the substrate to the passivation layer, an opening size of the photoresist after etching and widening being L1+L1′+L0+M0+M0′+M1+M1′, and in the direction from the substrate to the passivation layer, a size of the second layer of an opening being D1, and the first layer of an opening exposing the semiconductor layer; and depositing a gate structure, so as to form a gate portion and a field plate portion, the gate portion fully filling the first layer of an opening, and the field plate portion covering the gate portion and fully filling the second layer of an opening.

The gate structure provided by the embodiments of the present disclosure includes the gate portion and the field plate portion, the field plate portion includes the at least two field plate sub-portions, and in the direction from the gate portion to the field plate portion, the gate portion and the field plate portion are each divided into the two parts by the first plane. In the two adjacent field plate sub-portions, on the plane where the bottom surface, away from the lower field plate sub-portion, of the gate portion is located, the projection of the tail end point on the lower surface of the lower field plate sub-portion is located on the side, close to the first plane, of the projection of the start end point on the lower surface of the upper field plate sub-portion, and the start end point on the lower surface of the upper field plate sub-portion is coincidence with the end point where the upper surface of the lower field plate sub-portion is connected to the lower surface of the upper field plate sub-portion. The two adjacent field plate sub-portions are non-perpendicularly connected to each other, thereby achieving an effect of optimizing electric field distribution, thus improving reliability and stability of a semiconductor device.

It should be understood that the content described in this part are not intended to identify critical features or significant features of the embodiments of the present disclosure, or to limit the scope of the present disclosure. Other features of the present disclosure will be made easier to understand by the described below.

### BRIEF DESCRIPTION OF THE DRAWINGS

To make the illustration on the technical solutions in the embodiments of the present disclosure clearer, a brief introduction on the drawings to be used in the description of the embodiments will be presented below. It is obvious that the drawings described below are only some embodiments of the present disclosure, and as for an ordinary person skilled in this art, other drawings may be obtained according to these drawings without creative work.

FIG. 1 is a schematic structural diagram of a gate structure provided by an embodiment 1 of the present disclosure.

FIG. 2 is a schematic structural diagram of a gate structure provided by an embodiment 1 of the present disclosure.

FIG. 3 is a schematic structural diagram of a gate structure provided by an embodiment 1 of the present disclosure.

FIG. 4 is a schematic structural diagram of a gate structure provided by an embodiment 1 of the present disclosure.

FIG. 5 is a schematic structural diagram of a gate structure provided by an embodiment 2 of the present disclosure.

FIG. 6 is a schematic structural diagram of a gate structure provided by an embodiment 2 of the present disclosure.

FIG. 7 is a schematic structural diagram of a gate structure provided by an embodiment 3 of the present disclosure.

FIG. 8 is a schematic structural diagram of a gate structure provided by an embodiment 3 of the present disclosure.

FIG. 9 is a flow chart of a preparation method for a semiconductor device provided by an embodiment 4 of the present disclosure.

FIG. 10A to FIG. 10F are schematic structural diagrams of intermediate structures of the semiconductor device formed during a preparing process, provided by the embodiment 4 of the present disclosure.

FIG. 11 is a flow chart of a preparation method for a semiconductor device provided by an embodiment 5 of the present disclosure.

FIG. 12A to FIG. 12F are schematic structural diagrams of intermediate structures of the semiconductor device formed during a preparing process, provided by the embodiment 5 of the present disclosure.

### DETAILED DESCRIPTION OF THE EMBODIMENTS

To make a person skilled in this art understand the solutions of the present disclosure better, the technical solutions in the embodiments of the present disclosure will be clearly and completely described below in combination with the accompanying drawings therein. Obviously, the described embodiments are only some of the embodiments in the present disclosure, but not all of them. Based on the embodiments in the present disclosure, all of other embodiments obtained by an ordinary person skilled in this art without creative work shall be fallen within the protection scope of the present disclosure.

It should be noted that in the description and claims of the present disclosure and in the accompanying drawings above, the terms ‘comprising or including’, ‘having’, and any variations thereof are intended to cover non-exclusive inclusions. For example, a process, method, system, product or device including a series of steps or units is not limited to those steps or units that are clearly listed, but may include other steps or units that are not clearly listed or may include steps or units inherent to these processes, methods, products or devices.

In designing and preparing processes of semiconductor devices, a design of a gate portion and a gate field plate is particularly important, which plays a key role in reliability and stability of operational performance of semiconductor devices. A traditional design of the gate field plate has a limited effect on alleviating an electric field. In order to reduce the electric field of a gate, it is necessary to increase a length of a field plate or to reduce a distance between the field plate and a two-dimensional electron gas channel. Adopting these two methods, on the one hand, will increase an electric field at the gate field plate, thereby leading to a risk of dielectric breakdown at the field plate; on the other hand, adopting these two methods will lead to an increase in gate capacitance, thereby affecting bandwidth and high-frequency characteristics.

Therefore, it has been an urgent problem to further improve bandwidth and high-frequency characteristics of semiconductor devices, as well as their reliability and stability, so as to facilitate implementation of large-scale commercial production.

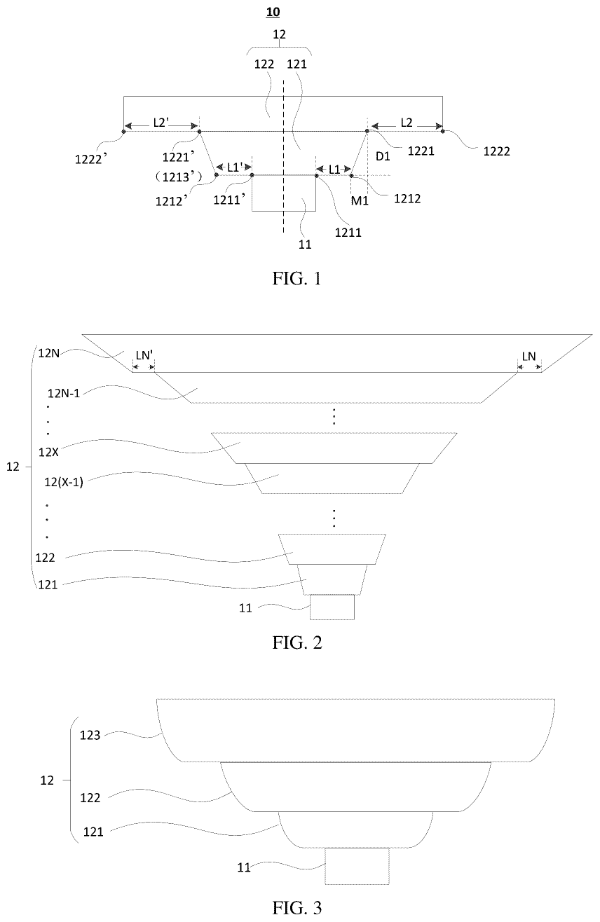

A gate structure, a semiconductor device and a preparation method for the semiconductor device in the embodiments of the present disclosure are described below in combination with FIG. 1 to FIG. 12F.

### Embodiment 1

FIG. 1 is a schematic structural diagram of a gate structure provided by an embodiment 1 of the present disclosure. As shown in FIG. 1, a gate structure 10 includes a gate portion 11 and a field plate portion 12. The field plate portion 12 includes at least two field plate sub-portions. In two adjacent field plate sub-portions, a field plate sub-portion away from the gate portion 11 is an upper field plate sub-portion, and a field plate sub-portion close to the gate portion 11 is a lower field plate sub-portion. In a direction from the gate portion 11 to the field plate portion 12, the gate portion 11 and the field plate portion 12 are each divided into two parts by a first plane (the plane in FIG. 1 where the dashed line is located), and the two parts are, respectively, a part on the left side of the dashed line and a part on the right side of the dashed line. In either of the two parts (the part on the left side of the dashed line or the part on the right side of the dashed line), on a plane where a bottom surface, away from the lower field plate sub-portion, of the gate portion 11 is located, a projection of a tail end point on a lower surface of the lower field plate sub-portion is located on a side, close to the gate portion 11 (or the first plane), of a projection of a start end point on a lower surface of the upper field plate sub-portion, and the start end point on the lower surface of the upper field plate sub-portion is coincidence with an end point where an upper surface of the lower field plate sub-portion is connected to the lower surface of the upper field plate sub-portion.

The first plane may be a bisector that is perpendicular to and bisects the plane where the bottom surface of the gate portion is located, or may only be a plane that is perpendicular to the plane where the bottom surface of the gate portion is located, which is not limited in the present disclosure.

An upper side is in a direction away from the gate portion 11, while a lower side is in a direction close to the gate portion 11, and therefore, an upper surface of one field plate sub-portion is a surface away from the gate portion 11, and a lower surface of one field plate sub-portion is a surface close to the gate portion 11. On a surface, on a same side, of a same field plate sub-portion, a start end point is an end point on the surface, on the side, of the field plate sub-portion, in a direction close to the gate portion 11, i.e., an end point, close to the first plane, on the surface on the side, and a tail end point is an end point on the surface, on the side, of the field plate sub-portion, in a direction away from the gate portion 11, i.e., an end point, away from the first plane, on the surface on the side. In other words, the start end point and the tail end point on one surface always exist in pair.

In this embodiment, the field plate portion 12 includes a first field plate sub-portion 121 (i.e., the lower field plate sub-portion) and a second field plate sub-portion 122 (i.e., the upper field plate sub-portion) that are sequentially arranged in a direction away from the gate portion 11. As shown in FIG. 1, in the part on the left side of the dashed line, the tail end point 1212′ on the lower surface of the first field plate sub-portion 121 is located on the side, close to the gate portion 11 (or the first plane), of the start end point 1221′ on the lower surface of the second field plate sub-portion 122. The start end point 1221′ on the lower surface of the second field plate sub-portion 122 is coincidence with an end point 1213′ where the upper surface of the first field plate sub-portion 121 is connected to the lower surface of the second field plate sub-portion 122. Similarly, in the part on the right side of the dashed line, there is also a position relationship between each end point as described above, and no repetition will be shown herein.

FIG. 2 is a schematic structural diagram of a gate structure provided by an embodiment 1 of the present disclosure. Referring to FIG. 2, which exemplifies that the field plate portion 12 includes the first field plate sub-portion 121, the second field plate sub-portion 122, . . . , a Nth field plate sub-portion 12N that are sequentially arranged in the direction away from the gate portion 11. As shown in FIG. 2, in two adjacent field plate sub-portions, a field plate sub-portion away from the gate portion 11 is a Xth field plate sub-portion 12X, and a field plate sub-portion close to the gate portion 11 is a (X−1)th field plate sub-portion 12 (X−1), where 1<X≤N. A tail end point on a lower surface of the (X−1)th field plate sub-portion 12 (X−1) (i.e., the lower field plate sub-portion) is located on a side, close to the gate portion 11, of a start end point on a lower surface of the Xth field plate sub-portion 12X (i.e., the upper field plate sub-portion), and the start end point on the lower surface of the Xth field plate sub-portion 12X (i.e., the upper field plate sub-portion) is coincidence with an end point where an upper surface of the (X−1)th field plate sub-portion 12 (X−1) is connected to the lower surface of the Xth field plate sub-portion 12X.

The two adjacent field plate sub-portions are non-perpendicularly connected to each other, that is, a side surface of the lower field plate sub-portion and the lower surface of the upper field plate sub-portion are non-perpendicularly connected to each other, thereby achieving an effect of optimizing electric field distribution, thus improving reliability and stability of semiconductor devices.

In an alternative embodiment, a side surface of a Nth field plate sub-portion 12N located at a topmost position (i.e., the field plate sub-portion farthest from the gate portion 11) may be a side surface perpendicular to the upper surface of the lower field plate sub-portion (i.e., a (N−1)th field plate sub-portion 12 (N−1)) adjacent to the Nth field plate sub-portion 12N, or may be a side surface non-perpendicular to the upper surface of the lower field plate sub-portion (i.e., the (N−1)th field plate sub-portion 12 (N−1)) adjacent to the Nth field plate sub-portion 12N.

In other embodiments, the field plate portion may include a plurality of field plate sub-portions, preferably, the field plate portion includes N field plate sub-portions, where N∈[2,4], and the N is an integer.

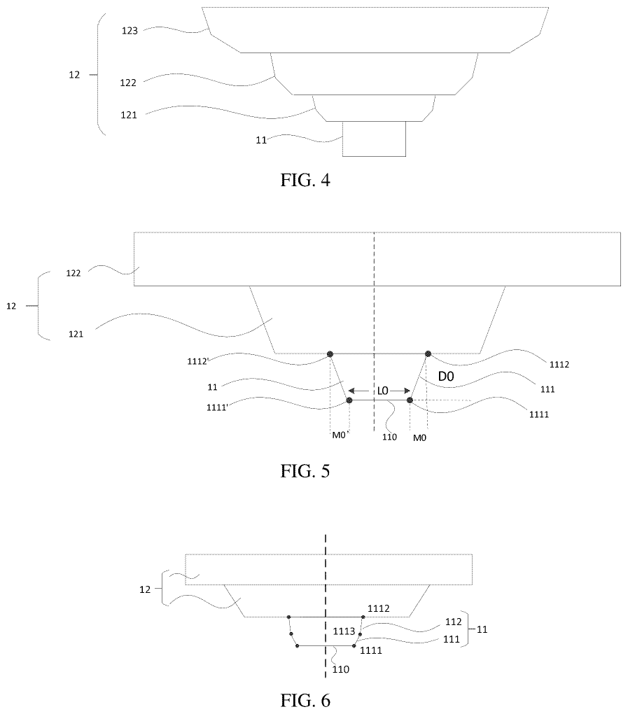

FIG. 1 and FIG. 2 exemplify a connection mode between two adjacent field plate sub-portions. In one embodiment, as shown in FIG. 3, the two adjacent field plate sub-portions are connected by a curved line, that is, the side surfaces of the lower field plate sub-portion and the upper field plate sub-portion are curved surfaces. In an alternative embodiment, as shown in FIG. 4, the two adjacent field plate sub-portions are connected by a multi-facetted surface, that is, the side surfaces of the lower field plate sub-portion and the upper field plate sub-portion are multi-facetted surfaces.

In an alternative embodiment, when the field plate portion 12 shown in FIG. 2 includes three field plate sub-portions, i.e., N=3, a side surface of a third field plate sub-portion 123 located at a topmost position may be a side surface perpendicular to the upper surface of the lower field plate sub-portion 122 adjacent to the third field plate sub-portion 123, or may be a curved surface.

In the part on the right side of the dashed line, a position relationship between two adjacent field plate sub-portions is: M (X−1)<L (X−1) and M (X−1)<D (X−1), where the X is an integer greater than or equal to 2. Similarly, in the part on the left side of the dashed line, there is also a position relationship between the two adjacent field plate sub-portions as described above, and no repetition will be shown herein.

Optionally, taking FIG. 1 as an example, in the part on the right side of the dashed line, the position relationship between the two adjacent field plate sub-portions is: M1<L1 and M1<D1.

On the plane where the bottom surface of the gate portion 11 is located, the M1 represents a distance between the projection of the start end point 1221 on the lower surface of the second field plate sub-portion 122 (i.e., the upper field plate sub-portion) and the projection of the tail end point 1212 on the lower surface of the first field plate sub-portion 121 (i.e., the lower field plate sub-portion), and the L1 represents a distance between a projection of a start end point 1211 on the lower surface of the first field plate sub-portion 121 (i.e., the lower field plate sub-portion) and the projection of the tail end point 1212 on the lower surface of the first field plate sub-portion 121 (i.e., the lower field plate sub-portion); and on a plane perpendicular to the plane where the bottom surface of the gate portion 11 is located, the D1 represents a distance between a projection of the start end point 1221 on the lower surface of the second field plate sub-portion 122 (i.e., the upper field plate sub-portion) and a projection of the tail end point 1212 on the lower surface of the first plate field sub-portion 121 (i.e., the lower field plate sub-portion).

In this way, a non-perpendicular connection between the two adjacent field plate sub-portions can be achieved, which can reduce a stray capacitance of a source or of a drain, thereby improving bandwidth and high-frequency characteristics of semiconductor devices.

In the part on the right side of the dashed line, a position relationship between the two adjacent field sub-portions is: L (X−1)<LX, where the X is an integer greater than or equal to 2. Similarly, in the part on the left side of the dashed line, there is also a position relationship between the two adjacent field plate sub-portions as described above, and no repetition will be shown herein.

Optionally, taking FIG. 1 as an example, in the part on the right side of the dashed line, the position relationship between the two adjacent field plate sub-portions is L1<L2.

In the plane where the bottom surface of the gate portion 11 is located, the L1 represents a distance between the projection of the start end point 1211 on the lower surface of the first field plate sub-portion 121 (i.e., the lower field plate sub-portion) and the projection of the tail end point 1212 on the lower surface of the first field plate sub-portion 121 (i.e., the lower field plate sub-portion), and the L2 represents a distance between the projection of the start end point 1221 on the lower surface of the second field plate sub-portion 122 (i.e., the upper field plate sub-portion) and the projection of the tail end point 1222 on the lower surface of the second field plate sub-portion 122 (i.e., the upper field plate sub-portion).

In this way, electric field distribution under a field plate portion can be optimized, thereby reducing a risk of dielectric breakdown at the field plate portion.

It should be understood that the above exemplifies that when the field plate portion includes two field plate sub-portions, the position relationship between the two adjacent field plate sub-portions, and when the field plate portion includes a plurality of field plate sub-portions, the position relationship between any two adjacent field plate sub-portions in the plurality of field plate sub-portions also satisfies the above relationship, and no repetition will be shown herein. A connecting point (also known as an end point) mentioned in the present disclosure is only used for a cross-sectional view, while a connection surface is used in a three-dimensional structure, which does not limit the protection scope of the present disclosure.

Optionally, referring to FIG. 2, a position relationship between the gate portion 11 and the first field plate sub-portion 121 adjacent to the gate portion 11 (also known as a dimensional relationship between the first plate sub-portion 121, adjacent to the gate portion 11, on different sides of the gate portion 11) is: L1=L1′; and a position relationship between the Nth field plate sub-portion 12N farthest from the gate portion 11 and the (N−1)th field plate sub-portion 12 (N−1) (also known as a dimensional relationship between the Nth field plate sub-portion 12N, farthest from the gate portion 11, on different sides of the (N−1)th field plate sub-portion 12 (N−1) adjacent to the Nth field plate sub-portion 12N farthest from the gate portion 11) is: LN=LN′. In this way, an electric field on a side, close to a source, of a gate portion can be optimized, thus improving reliability and stability of semiconductor devices. In this embodiment, a structure of the gate portion 11 satisfies that M0=M0′. In this embodiment, both the gate portion 11 and the field plate portion 12 have a symmetrical structure.

In other embodiments, a position relationship between the gate portion 11 and the first field plate sub-portion 121 adjacent to the gate portion 11 is: L1>L1′; and a position relationship between the Nth field plate sub-portion 12N farthest from the gate portion 11 and the (N−1)th field plate sub-portion 12 (N−1) is LN>LN′. Since a gate-drain voltage is much greater than a gate-source voltage when a semiconductor device is working, this design specifies that L1>L1′ and LN>LN′, which can avoid a stray capacitance introduced by the L1′ and the LN′, thereby improving bandwidth and high-frequency characteristics of semiconductor devices. In this embodiment, a structure of the gate portion 11 satisfies that M0>M0′. In this embodiment, both the gate portion 11 and the field plate portion 12 have an asymmetric structure.

In other embodiments, a structure of the gate portion 11 satisfies that M0=M0′, a position relationship between the gate portion 11 and the first field plate sub-portion 121 adjacent to the gate portion 11 is: L1>L1′, and a position relationship between any group of two adjacent field plate sub-portions (for example, the Xth field plate sub-portion 12X and the (X−1)th field plate sub-portion 12 (X−1)) in the plurality of field plate sub-portions is LX>LX′, where the X is an integer greater than or equal to 2 but less than or equal to N. In this way, an electric field on a side, close to a source, of a gate portion can be optimized, thus improving reliability and stability of semiconductor devices. In this embodiment, the gate portion 11 has a symmetrical structure and the field plate portion 12 has an asymmetric structure.

In other embodiments, a structure of the gate portion 11 satisfies that M0=M0′, a position relationship between the gate portion 11 and the first field plate sub-portion 121 adjacent to the gate portion 11 is: L1=L1′, and a position relationship between any group of two adjacent field plate sub-portions (for example, the Xth field plate sub-portion 12X and the (X−1)th field plate sub-portion 12 (X−1)) in the plurality of field plate sub-portions is LX>LX′, where the X is greater than or equal to 2 but less than or equal to N. In this way, an electric field on a side, close to a source, of a gate portion can be optimized, thus improving reliability and stability of semiconductor devices. In this embodiment, both the gate portion 11 and the first field plate sub-portion 121 have a symmetric structure, and the other field plate sub-portions, except the first field plate sub-portion 121, in the plurality of field plate sub-portions have an asymmetric structure.

On the plane where the bottom surface of the gate portion 11 is located, the L1 represents a distance, on a side of the first plane (the right side of the dashed line), between the projection of the start end point on the lower surface of the first field plate sub-portion 121 adjacent to the gate portion 11 and the projection of the tail end point on the lower surface of the first field plate sub-portion 121 adjacent to the gate portion 11, and the L1′ represents a distance, on another side of the first plane (the left side of the dashed line), between the projection of the start end point on the lower surface of the first field plate sub-portion 121 adjacent to the gate portion 12 and the projection of the tail end point on the lower surface of the first field plate sub-portion 121 adjacent to the gate portion 12; and the LN represents a distance, on the side of the first plane (the right side of the dashed line), between the projection of the start end point on the lower surface of the Nth field plate sub-portion 12N farthest from the gate portion 11 and the projection of the tail end point on the lower surface of the Nth field plate sub-portion 12N farthest from the gate portion 11, and the LN′ represents a distance, on the another side of the first plane (the left side of the dashed line), between the projection of the start end point on the lower surface of the Nth field plate sub-portion 12N farthest from the gate portion 11 and the projection of the tail end point on the lower surface of the Nth field plate sub-portion 12N farthest from the gate portion 11.

The gate structure provided by the embodiments of the present disclosure may be widely applied to the fields such as RF microwave or power electronics. Especially for gallium-nitride electronic devices with large band gap, high electron mobility, high breakdown field strength and good thermal conductivity, the advantages are more obvious. A formed metal electrode is of good quality and good electrode stability, which significantly improves electrical performance of an electrode, thus better meeting high-performance requirements of the fields such as fast-growing electronic communications.

### Embodiment 2

FIG. 5 is a schematic structural diagram of a gate structure provided by an embodiment 2 of the present disclosure. Referring to FIG. 5, in the part on the right side of the dashed line, the gate portion 11 includes a bottom surface 110 away from the field plate portion 12 and a first side surface 111 connected to the bottom surface 110. Similarly, in the part on the left side of the dashed line, the gate portion 11 also includes a first side surface (not shown).

In the part on the right side of the dashed line, on a plane where the bottom surface 110 of the gate portion 11 is located, a projection of an end point 1112 where the gate portion 11 is connected to the first field plate sub-portion 121 of the field plate portion 12 is located on a side, away from the gate portion 11 (or, the first plane shown by the dashed line), of a projection of an end point 1111 where the bottom surface 110 is connected to the first side surface 111. In the part on the left side of the dashed line, a projection of an end point 1112′ where the gate portion 11 is connected to the first field plate sub-portion 121 of the field plate portion 12 is located on a side, away from the gate portion 11 (or, the first plane shown by the dashed line), of a projection of an end point 1111′ where the bottom surface 110 is connected to the first side surface 111.

The first side surface is located on a side, away from the plane where the bottom surface is located and close to a plane where the field plate portion 12 is located, of the end point 1111 on the bottom surface of the gate portion 11.

In this embodiment, there is no substantial difference between the end points 1111 and 1111′, as well as between the end points 1112 and 1112′. The end points 1111 and 1111′, as well as the end points 1112 and 1112′ are designated to distinguish whether endpoints are located on a same side of the first plane, the end points 1111 and 1112 are located on a same side, while the end points 1111′ and 1112′ are located on another side.

In the two parts, a position relationship between an upper surface of the gate portion 11 and the bottom surface 110 of the gate portion 11 (also known as a distance relationship between an end point where the gate portion 11 is connected to the field plate portion 12 and an end point where the bottom surface 110 is connected to the first side surface) is: M0<L0 and M0′<L0, preferably, the position relationship between the upper surface of the gate portion 11 and the bottom surface 110 of the gate portion 11 is: M0<L0/4 and M0′<L0/4.

A structure of the gate portion 11 satisfies that M0=M0′, which may make the gate structure better applied in the field of RF communications.

In other embodiments, in the two parts, a position relationship between an upper surface of the gate portion 11 and the bottom surface 110 of the gate portion 11 (also known as a distance relationship between an end point where the gate portion 11 is connected to the field plate portion 12 and the bottom surface 110 of the gate portion 11) is: M0≤D0 and M0′≤D0.

On the plane where the bottom surface of the gate portion 11 is located, the M0 represents a distance, on a side of the first plane (i.e., the right side of the dashed line), between a projection of the end point 1112 where the gate portion 11 is connected to the first field plate sub-portion 121 of the field plate portion 12 and a projection of the end point 1111 where the bottom surface 110 is connected to the first side surface 111, and the M0′ represents a distance, on another side of the first plane (i.e., the left side of the dashed line), between a projection of the end point 1112′ where the gate portion 11 is connected to the first field plate sub-portion 121 of the field plate portion 12 and a projection of the end point 1111′ where the bottom surface 110 is connected to the first side surface 111; the L0 represents a distance between the projection of the end point 1111, on the side of the first plane, where the bottom surface 110 is connected to the first side surface 111 and the projection of the end point 1111′, on the another side of the first plane, where the bottom surface 110 is connected to the first side surface 111; and the D0 represents a perpendicular distance between the upper surface of the gate portion 11 and the bottom surface.

In an alternative embodiment, the upper surface of and the bottom surface 110 of the gate portion 11 are connected by a facetted surface, i.e., a side surface formed by connecting the end point 1112, on the side of the first plane, where the gate portion 11 is connected to the first field plate sub-portion 121 of the field plate portion 12 to the end point 1111, on the side of the first plane, where the bottom surface 110 is connected to the first side surface 111 may be a multi-facetted surface, as long as M0≤D0 is satisfied. Similarly, a side surface formed by connecting the end point 1112′, on the another side of the first plane, where the gate portion 11 is connected to the first field plate sub-portion 121 of the field plate portion 12 to the end point 1111′, on the another side of the first plane, where the bottom surface 110 is connected to the first side surface 111 may also be a multi-facetted surface, as long as M0′≤D0 is satisfied.

That is to say, a connection relationship between the bottom surface 110 and the first side surface 111, or between the first side surface 111 and a lower surface of the field plate portion 12, is a non-perpendicular connection, and a distance between the end point 1111 where the bottom surface 110 is connected to the first side surface 111 and the end point 1112 where the gate portion 11 is connected to the field plate portion 12 is balanced, thus improving frequency characteristics.

In this way, a stray capacitance can be reduced, thereby improving bandwidth and high-frequency characteristics of semiconductor devices.

FIG. 6 is a schematic structural diagram of a gate structure provided by an embodiment 2 of the present disclosure. As shown in FIG. 6, the gate portion 11 also includes a second side surface 112, an end point 1113 where an end of the second side surface 112 is connected to the first side surface 111 and an end point where and the second side surface 112 is connected to the field plate portion 12 are located on a same side of the first plane.

In an embodiment, on the plane where the bottom surface 110 is located, a projection of the end point 1112 where the second side surface 112 is connected to the field plate portion 12 is located at a side, away from the end point 1111 where the bottom surface 110 is connected to the first side surface 111 (or, the first plane), of a projection of the end point 1113 where the end of the second side surface 112 is connected to the first side surface 111. In another embodiment, on the plane where the bottom surface 110 is located, the projection of the end point 1112 where the second side surface 112 is connected to the field plate portion 12 is coincidence with the end point 1113 where the end of the second side surface 112 is connected to the first side surface 111.

A side surface formed by connecting the end point 1111 where the bottom surface 110 is connected to the first side surface 111 to the end point 1112 where the gate portion 11 is connected to the first field plate sub-portion 121 of the field plate portion 12 may be either a flat surface or a curved surface. In an alternative embodiment, the end point 1111 where the bottom surface 110 is connected to the first side surface 111 and the end point 1112 where the gate portion 11 is connected to the first field plate sub-portion 121 of the field plate portion 12 are connected by a multi-facetted surface.

### Embodiment 3

FIG. 7 is a schematic structural diagram of a semiconductor device provided by an embodiment 3 of the present disclosure. As shown in FIG. 7, the semiconductor device includes a substrate 60, a semiconductor layer 50, a source 20, a drain 30, a passivation layer 40, and a gate structure 10. The semiconductor layer 50 is formed on a side of the substrate 60, the source 20 and drain 30 are formed on a side, away from the substrate 60, of the semiconductor layer 50, the passivation layer 40 is formed on the side, away from the substrate 60, of the semiconductor layer 50, and the gate structure 10 is formed on a side, away from the substrate 60, of the passivation layer 40. Combined with FIG. 1, it can be seen that a field plate portion 12 of the gate structure 10 is located on a side, away from the semiconductor layer 50, of a gate portion 11 of the gate structure 10.

Preferably, in an embodiment of the present disclosure, a material of the passivation layer includes silicon nitride and/or silicon nitride oxide. The substrate may be made of one of silicon, sapphire, silicon carbide, or gallium arsenide, and the semiconductor layer may be made of at least one of gallium nitride, aluminum gallium nitride, or indium gallium nitride.

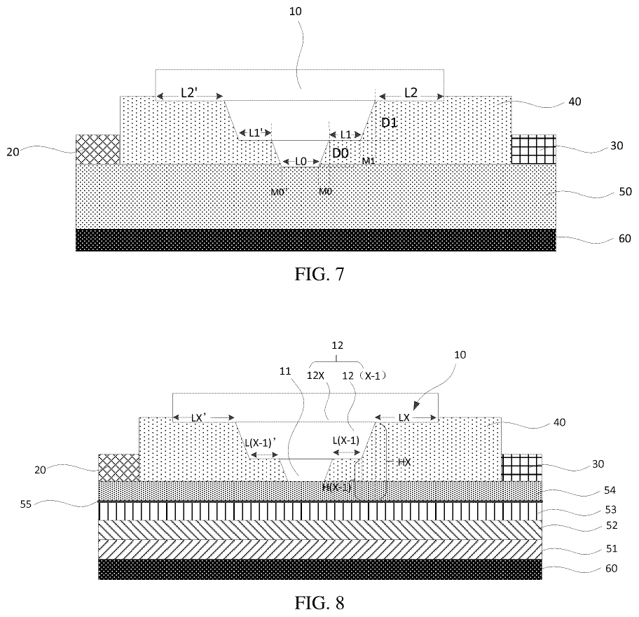

On the basis of the above-mentioned embodiments, as shown in FIG. 8, the semiconductor layer 50 also includes a nucleation layer 51, a buffer layer 52, a channel layer 53, a barrier layer 54 and a cap layer (not shown) that are sequentially arranged in a direction away from the substrate 60. In this embodiment, the barrier layer 54 is in contact with the source 20 and the drain 30 respectively, to form an ohmic contact. The channel layer 53 and the barrier layer 54 form a heterojunction together, and a two-dimensional electron gas layer 55 is formed at the heterojunction. A bottom surface of the gate portion 11 may be in contact with an upper surface, away from substrate 60, of the barrier layer 54, or may be located inside the barrier layer 54.

In the part on the right side of the dashed line, a position relationship between two adjacent field plate sub-portions and the two-dimensional electron gas layer 55 is: L(X−1)<5.5*H(X−1) and LX<5.5*HX, where the X is an integer greater than or equal to 2. Similarly, in the part on the left side of the dashed line, there is also a position relationship between two adjacent field plate sub-portions and the two-dimensional electron gas layer 55 as described above, and no repetition will be shown herein.

Taking FIG. 8 as an example, when X=2, the position relationship between the two adjacent field plate sub-portions and the two-dimensional electron gas layer 55 is L1<5.5*H1 and L2<5.5*H2. According to a position relationship between the bottom surface of the gate portion 11 and the barrier layer 54, a relationship between the D0, the L1, the D1 and the L2 may be adjusted appropriately to satisfy requirements on distance between the field plate portion 12 and the two-dimensional electron gas layer 55.

In the part on the right side of the dashed line, on the plane where the bottom surface of the gate portion 11 is located, the L (X−1) represents a distance between a projection of a start end point on a lower surface of a (X−1)th field plate sub-portion 12 (X−1) (i.e., a lower field plate sub-portion) and a projection of a tail end point on the lower surface of the (X−1)th field plate sub-portion 12 (X−1), and the LX represents a distance between a projection of a start end point on a lower surface of a Xth field plate sub-portion 12X (i.e., an upper field plate sub-portion) and a projection of a tail end point on the lower surface of the Xth field plate sub-portion 12X. The H (X−1) represents a perpendicular distance between the lower surface of the (X−1)th field plate sub-portion 12 (X−1) and the two-dimensional electron gas layer 55. The HX represents a perpendicular distance between the lower surface of the Xth field plate sub-portion 12X and the two-dimensional electron gas layer 55.

When L (X−1)>5.5*H (X−1) (together with that LX>5.5*HX), a length of the field plate portion 12 is further increased, which does not provide further relief to an electric field but rather increases a stray capacitance. Since the distance between the field plate portion 12 and the two-dimensional electron gas layer 55 has a great influence on device performance, a thickness of the field plate portion 12 may be adjusted by adjusting a depth to which the bottom surface of the gate portion 11 extends into the semiconductor layer 50, so as to achieve control on ranges of the D2 and the D3, thereby achieving adjustable settings of different power devices.

A gallium nitride RF device is formed using a structure of the semiconductor device in the present disclosure, so that power and frequency of a gallium nitride RF device may be improved on the premise of maintaining stable performance of semiconductor devices, so as to be more suitable for the field of high-frequency 5G communications.

In the above-mentioned specific embodiments, the end point is only for the cross-sectional view, while a connection surface is used in a three-dimensional structure, which does not limit the protection scope of the present disclosure.

### Embodiment 4

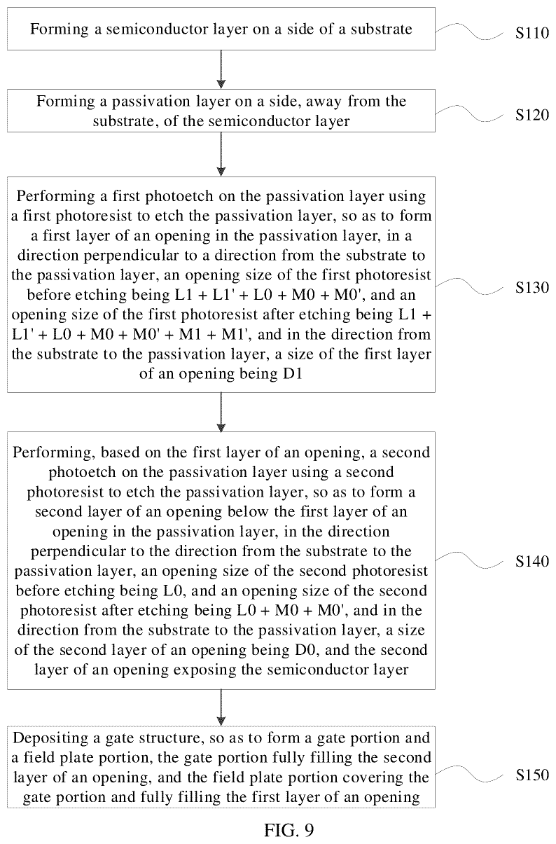

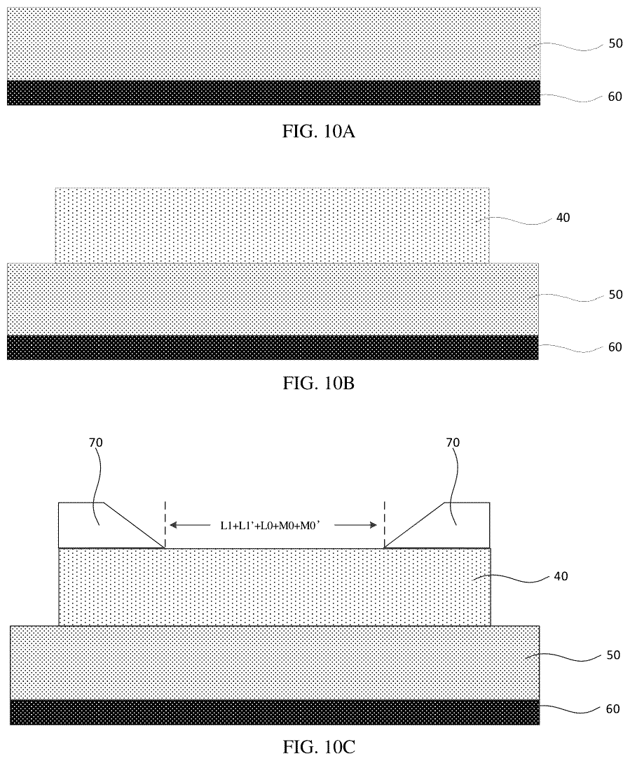

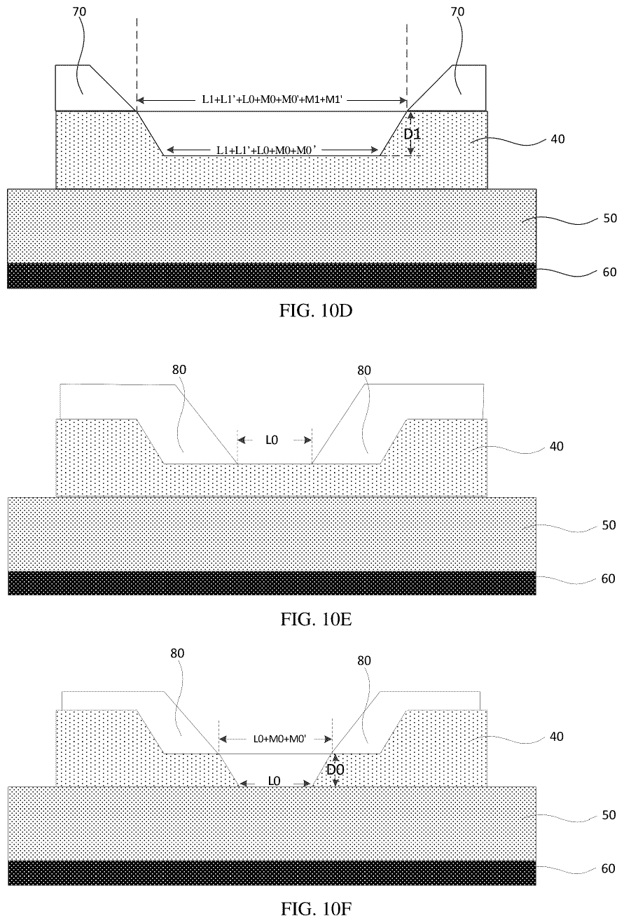

FIG. 9 is a flow chart of a preparation method for a semiconductor device provided by an embodiment 4 of the present disclosure, which is used to prepare the above-mentioned semiconductor device. FIG. 10A to FIG. 10F are schematic structural diagrams of intermediate structures of the semiconductor device formed during a preparing process, provided by the embodiment 4 of the present disclosure. Referring to FIG. 10A to FIG. 10F, the preparation method includes:
S110, forming a semiconductor layer 50 on a side of a substrate 60.
S120, forming a passivation layer 40 on a side, away from the substrate 60, of the semiconductor layer 50.
S130, performing a first photoetch on the passivation layer 40 using a first photoresist 70 to etch the passivation layer 40, so as to form a first layer of an opening in the passivation layer 40, in a direction perpendicular to a direction from the substrate 60 to the passivation layer 40, an opening size (also known as a width) of the first photoresist before etching being L1+L1′+L0+M0+M0′, and an opening size of the first photoresist after etching being L1+L1′+L0+M0+M0′+M1+M1′, and in the direction from the substrate 60 to the passivation layer 40, a size (also known as a depth) of the first layer of an opening being D1.

Specifically, referring to FIG. 10C and FIG. 10D, the first photoresist 70 is formed on a side, away from the semiconductor layer 50, of the passivation layer 40, and an opening with a size of L1+L1′+L0+M0+M0′ is reserved. At an opening position, the first photoetch is performed on the passivation layer 40, and the opening size of the first photoresist after etching (i.e., the size of the first layer of an opening) is L1+L1′+L0+M0+M0′+M1+M1′. In this embodiment, in a process of etching the passivation layer 40 based on the first photoresist 70 to form the first layer of an opening, not only is the passivation layer 40 etched, but also the first photoresist 70 at an edge of the first layer of an opening is simultaneously etched, and therefore, the opening size of the first photoresist after etching is greater than the opening size of the first photoresist before etching. A side surface of the first layer of an opening has a certain slope degree. In this embodiment, before being etched, the first photoresist 70 is roughly wedged-shaped, and tips of the wedges of the first photoresist 70 on both sides of the opening are oriented towards the opening, preferably, an inclined angle of the tip of the first photoresist 70 is different from that of the passivation layer 40 after etching.
S140, performing, based on the first layer of an opening, a second photoetch on the passivation layer 40 using a second photoresist 80 to etch the passivation layer 40, so as to form a second layer of an opening below the first layer of an opening in the passivation layer 40, in the direction perpendicular to the direction from the substrate 60 to the passivation layer 40, an opening size of the second photoresist 80 before etching being L0, and an opening size of the second photoresist 80 after etching being L0+M0+M0′, and in the direction from the substrate 60 to the passivation layer 40, a size of the second layer of an opening being D0, and the second layer of an opening exposing the semiconductor layer 50.

Referring to FIG. 10E and FIG. 10F, the second photoresist 80 is formed on a lower surface (a bottom surface) of the first layer of an opening, and an opening with a size of L0 is reserved. At an opening position, the second photoetch is performed on the passivation layer 40, and the opening size of the second photoresist 80 after etching is L0+M0+M0′.

In this embodiment, in a process of etching the passivation layer 40 based on the second photoresist 80 on the bottom surface of the first layer of an opening to form the second layer of an opening, not only is the passivation layer 40 etched, but also the second photoresist 80 at an edge of the second layer of an opening is simultaneously etched, and therefore, the opening size of the second photoresist 80 after etching is greater than the opening size of the second photoresist 80 before etching. A side surface of the second layer of an opening may also have a certain slope degree. In this embodiment, before being etched, the second photoresist 80 is roughly wedged-shaped, and tips of the wedges of the second photoresist 80 on both sides of the opening are oriented towards the opening, preferably, an inclined angle of the tip of the second photoresist 80 is different from that of the passivation layer 40 after etching.
S150, depositing a gate structure 10, so as to form a gate portion 11 and a field plate portion 12, the gate portion 11 fully filling the second layer of an opening, and the field plate portion 12 covering the gate portion 11 and fully filling the first layer of an opening.

In an alternative embodiment, after the semiconductor layer 50 is formed, the preparation method further includes forming a source 20 and a drain 30, and then forming the passivation layer 40 covering the source 20 and the drain 30 on the side, away from the substrate 60, of the semiconductor layer 50. In other alternative embodiments, after the passivation layer 40 is formed on the side, away from the substrate 60, of the semiconductor layer 50, an opening is correspondingly made in the passivation layer 40 to expose the semiconductor layer 50, and the source 20 and the drain 30 are formed in the opening. In this embodiment, the source 20 and the drain 30 are located on both sides of the gate structure 10.

### Embodiment 5

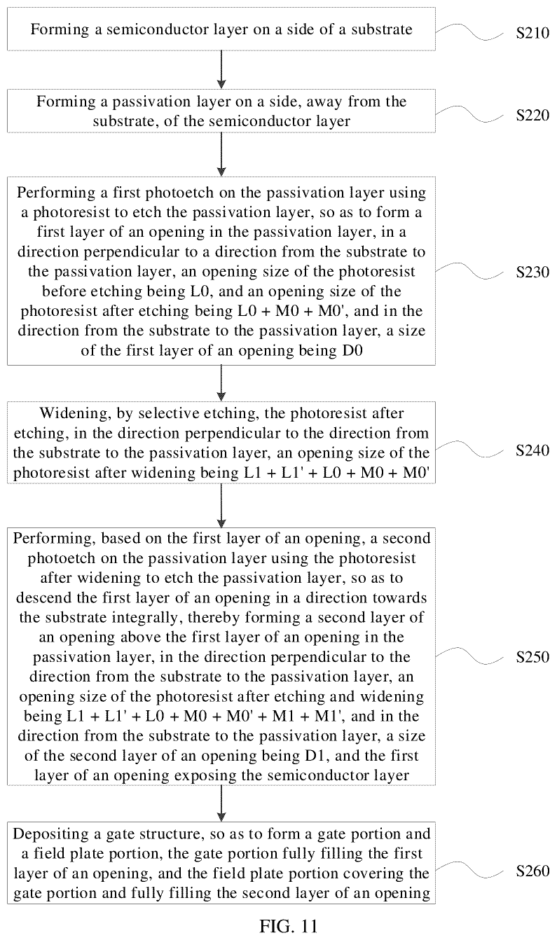

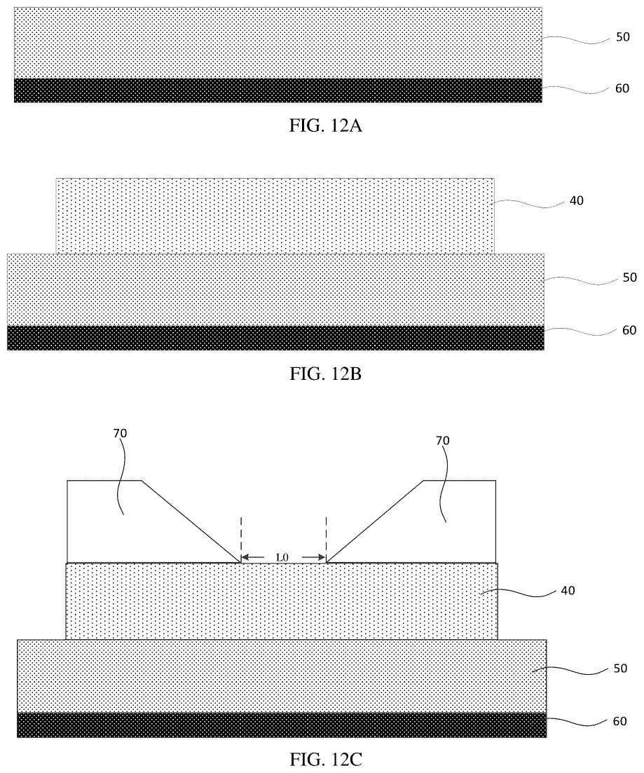

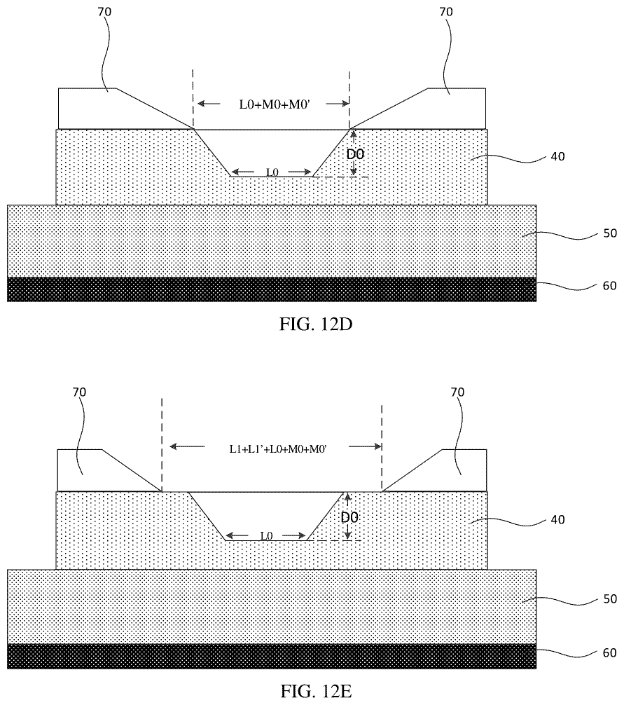

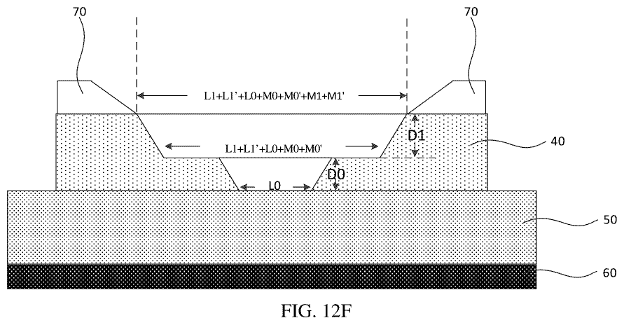

FIG. 11 is a flow chart of a preparation method for a semiconductor device provided by an embodiment 5 of the present disclosure, which is used to prepare the semiconductor device mentioned in the above embodiments. FIG. 12A to FIG. 12F are schematic diagrams of a preparing process for the semiconductor device provided by the embodiment 5 of the present disclosure. Referring to FIG. 12A to FIG. 12F, the preparation method includes:
S210, forming a semiconductor layer 50 on a side of a substrate 60.
S220, forming a passivation layer 40 on a side, away from the substrate 60, of the semiconductor layer 50.
S230, performing a first photoetch on the passivation layer 40 using a photoresist 70 to etch the passivation layer 40, so as to form a first layer of an opening in the passivation layer 40, in a direction perpendicular to a direction from the substrate 60 to the passivation layer 40, an opening size of the photoresist 70 before etching being L0, and an opening size of the photoresist 70 after etching being L0+M0+M0′, and in the direction from the substrate 60 to the passivation layer 40, a size of the first layer of an opening being D0.

Specifically, referring to FIG. 12C and FIG. 12D, the photoresist 70 is formed on a side, away from the semiconductor layer 50, of the passivation layer 40, and an opening with a size of L0 is reserved. At an opening position, the first photoetch is performed on the passivation layer 40, and the opening size of the photoresist 70 after etching (i.e., an opening size of the first layer of an opening) is L0+M0+M0′. In this embodiment, in a process of etching the passivation layer 40 based on the photoresist 70 to form the first layer of an opening, not only is the passivation layer 40 etched, but also the photoresist 70 at an edge of the first layer of an opening is simultaneously etched, and therefore, the opening size of the photoresist 70 after etching is greater than the opening size of the photoresist 70 before etching. A side surface of the first layer of an opening has a certain slope degree. In this embodiment, before being etched, the photoresist 70 close to the opening is roughly wedged-shaped, and tips of the wedges of the photoresist 70 on both sides of the opening are oriented towards the opening, preferably, an inclined angle of the tip of the photoresist 70 is different from that of the passivation layer 40 after etching.
S240, widening, by selective etching, the photoresist 70 after etching, in the direction perpendicular to the direction from the substrate 60 to the passivation layer 40, an opening size of the photoresist 70 after widening being L1+L1′+L0+M0+M0′.
S250, performing, based on the first layer of an opening, a second photoetch on the passivation layer 40 using the photoresist 70 after widening to etch the passivation layer 40, so as to descend the first layer of an opening in a direction towards the substrate 60 integrally, thereby forming a second layer of an opening above the first layer of an opening in the passivation layer 40, in the direction perpendicular to the direction from the substrate 60 to the passivation layer 40, an opening size of the photoresist 70 after etching and widening being L1+L1′+L0+M0+M0′ +M1+M1′, and in the direction from the substrate 60 to the passivation layer 40, a size of the second layer of an opening being D1, and the first layer of an opening exposing the semiconductor layer 50.

In this embodiment, in a process of etching the passivation layer 40 based on the photoresist 70 after widening to form the second layer of an opening, not only is the passivation layer 40 etched, but also the photoresist 70 at an edge of the second layer of an opening is simultaneously etched, and therefore, the opening size of the photoresist 70 after etching is greater than the opening size of the photoresist 70 before etching. A side surface of the second layer of an opening may also have a certain slope degree. In this embodiment, before being etched, the photoresist 70 close to the opening is roughly wedged-shaped, and tips of the wedges of the photoresist 70 on both sides of the opening are oriented towards the opening, preferably, an inclined angle of the tip of the photoresist 70 is different from that of the passivation layer 40 after etching.
S260, depositing a gate structure 10, so as to form a gate portion 11 and a field plate portion 12, the gate portion 11 fully filling the first layer of an opening, and the field plate portion 12 covering the gate portion 11 and fully filling the second layer of an opening.

In an alternative embodiment, after the semiconductor layer 50 is formed, the preparation method further includes forming a source 20 and a drain 30, and then forming the passivation layer 40 covering the source 20 and the drain 30 on the side, away from the substrate 60, of the semiconductor layer 50. In other alternative embodiments, after the passivation layer 40 is formed on the side, away from the substrate 60, of the semiconductor layer 50, an opening is correspondingly made in the passivation layer 40 to expose the semiconductor layer 50, and the source 20 and the drain 30 are formed in the opening. In this embodiment, the source 20 and the drain 30 are located on both sides of the gate structure 10.

In an alternative embodiment, the photoresist in the above-mentioned embodiments may also be of the same thickness for preparing an opening without slope surface.

It should be understood that steps of reordering, adding, or deleting might be made using the procedures, in various forms, shown above. For example, the steps described in the present disclosure may be performed in parallel or sequentially or in different order, as long as the desired results of the technical solutions of the present disclosure can be achieved, which is not limited herein.

The above-mentioned specific embodiments do not constitute a limitation on the protection scope of the present disclosure. It should be understood by the person skilled in this art that various modifications, combinations, sub-combinations, and replacements may be made depending on design requirements and other factors. Any modification, equivalent replacement and improvement made within the spirit and principles of the present disclosure shall be included in the protection scope of the present disclosure.

What is claimed is:

1. A gate structure, comprising a gate portion and a field plate portion,
wherein the field plate portion comprises at least two field plate sub-portions;
in two adjacent field plate sub-portions, a field plate sub-portion away from the gate portion is an upper field plate sub-portion, and a field plate sub-portion close to the gate portion is a lower field plate sub-portion;
in a direction from the gate portion to the field plate portion, the gate portion and the field plate portion are each divided into two parts by a first plane, and in either of the two parts, on a plane where a bottom surface, away from the lower field plate sub-portion, of the gate portion is located, a projection of a tail end point on a lower surface of the lower field plate sub-portion is located on a side, close to the first plane, of a projection of a start end point on a lower surface of the upper field plate sub-portion, and the start end point on the lower surface of the upper field plate sub-portion is coincidence with an end point where an upper surface of the lower field plate sub-portion is connected to the lower surface of the upper field plate sub-portion; and
an upper surface of one field plate sub-portion is a surface away from the gate portion, and a lower surface of one field plate sub-portion is a surface close to the gate portion; and on a surface, on a same side, of a same field plate sub-portion, a start end point is an end point, close to the first plane, of the surface of the field plate sub-portion, and a tail end point is an end point, away from the first plane, of the surface of the field plate sub-portion.

2. The gate structure according to claim 1, wherein in either of the two parts, a position relationship between the two adjacent field plate sub-portions is: M (X−1)<L (X−1), and M (X−1)<D (X−1), wherein the X is an integer equal to or greater than 2;
on the plane where the bottom surface of the gate portion is located, the M (X−1) represents a distance between the projection of the start end point on the lower surface of the upper field plate sub-portion and the projection of the tail end point on the lower surface of the lower field plate sub-portion, and the L (X−1) represents a distance between a projection of a start end point on the lower surface of the lower field plate sub-portion and the projection of the tail end point on the lower surface of the lower field plate sub-portion; and
on a plane perpendicular to the plane where the bottom surface of the gate portion is located, the D (X−1) represents a distance between a projection of the tail end point on the lower surface of the lower field plate sub-portion and a projection of the end point where the upper surface of the lower field plate sub-portion is connected to the lower surface of the upper field plate sub-portion.

3. The gate structure according to claim 1, wherein in either of the two parts, a position relationship between the two adjacent field plate sub-portions is: L (X−1)<LX, wherein the X is an integer equal to or greater than 2; and
on the plane where the bottom surface of the gate portion is located, the L (X−1) represents a distance between a projection of a start end point on the lower surface of the lower field plate sub-portion and the projection of the tail end point on the lower surface of the lower field plate sub-portion, and the LX represents a distance between the projection of the start end point on the lower surface of the upper field plate sub-portion and a projection of a tail end point on the lower surface of the upper field plate sub-portion.

4. The gate structure according to claim 1, wherein in either of the two parts, the gate portion comprises the bottom surface away from the field plate portion and a first side surface connected to the bottom surface, and on the plane where the bottom surface of the gate portion is located, a projection of an end point where the gate portion is connected to the field plate portion is located on a side, away from the first plane, of a projection of an end point where the bottom surface is connected to the first side surface;
in the two parts, a distance relationship between the end point where the gate portion is connected to the field plate portion and the end point where the bottom surface is connected to the first side surface is: M0<L0 and M0′<L0; and
on the plane where the bottom surface of the gate portion is located, the M0 represents a distance, on a side of the first plane, between the projection of the end point where the gate portion is connected to the field plate portion and the projection of the end point where the bottom surface is connected to the first side surface, and the M0′ represents a distance, on another side of the first plane, between the projection of the end point where the gate portion is connected to the field plate portion and the projection of the end point where the bottom surface is connected to the first side surface; and the L0 represents a distance between the projection of the end point, on the side of the first plane, where the bottom surface is connected to the first side surface and the projection of the end point, on the another side of the first plane, where the bottom surface is connected to the first side surface.

5. The gate structure according to claim 4, wherein M0<L0/4 and M0′<L0/4.

6. The gate structure according to claim 4, wherein M0=M0′.

7. The gate structure according to claim 4, wherein in either of the two parts, the gate portion further comprises a second side surface, an end of the second side surface is connected to the first side surface, and another end of the second side surface is connected to the field plate portion,
wherein a position relationship between an end point where the second side surface is connected to the field plate portion and an end point where the first side surface is connected to the second side surface comprises:
on the plane where the bottom surface of the gate portion is located, a projection of the end point where the second side surface is connected to the field plate portion being located on a side, away from the first plane, of a projection of the end point where the first side surface is connected to the second side surface,
or, on the plane where the bottom surface of the gate portion is located, a projection of the end point where the second side surface is connected to the field plate portion being coincidence with a projection of the end point where the first side surface is connected to the second side surface.

8. The gate structure according to claim 1, wherein in either of the two parts, the gate portion comprises the bottom surface away from the field plate portion and a first side surface connected to the bottom surface, and on the plane where the bottom surface of the gate portion is located, a projection of an end point where the gate portion is connected to the field plate portion is located on a side, away from the first plane, of a projection of an end point where the bottom surface is connected to the first side surface;
in the two parts, a distance relationship between the bottom surface of the gate portion and the end point where the gate portion is connected to the field plate portion is: M0≤D0 and M0′≤D0; and
on the plane where the bottom surface of the gate portion is located, the M0 represents a distance, on a side of the first plane, between the projection of the end point where the gate portion is connected to the field plate portion and the projection of the end point where the bottom surface is connected to the first side surface, and the M0′ represents a distance, on another side of the first plane, between the projection of the end point where the gate portion is connected to the field plate portion and the projection of the end point where the bottom surface is connected to the first side surface; and the D0 represents a perpendicular distance between an upper surface, close to the field plate portion, of the gate portion and the bottom surface of the gate portion.

9. The gate structure according to claim 8, wherein M0=M0′.

10. The gate structure according to claim 8, wherein in either of the two parts, the gate portion further comprises a second side surface, an end of the second side surface is connected to the first side surface, and another end of the second side surface is connected to the field plate portion,
wherein a position relationship between an end point where the second side surface is connected to the field plate portion and an end point where the first side surface is connected to the second side surface comprises:
on the plane where the bottom surface of the gate portion is located, a projection of the end point where the second side surface is connected to the field plate portion being located on a side, away from the first plane, of a projection of the end point where the first side surface is connected to the second side surface,
or, on the plane where the bottom surface of the gate portion is located, a projection of the end point where the second side surface being connected to the field plate portion is coincidence with a projection of the end point where the first side surface is connected to the second side surface.

11. A gate structure, comprising a gate portion and a field plate portion,
wherein in a direction from the gate portion to the field plate portion, the gate portion and the field plate portion are each divided into two parts by a first plane, and in either of the two parts, the gate portion comprises a bottom surface away from the field plate portion and a first side surface connected to the bottom surface, and on a plane where the bottom surface of the gate portion is located, a projection of an end point where the gate portion is connected to the field plate portion is located on a side, away from the first plane, of a projection of an end point where the bottom surface is connected to the first side surface;
in the two parts, a distance relationship between the end point where the gate portion is connected to the field plate portion and the end point where the bottom surface is connected to the first side surface is: M0<L0 and M0′<L0; and
on the plane where the bottom surface of the gate portion is located, the M0 represents a distance, on a side of the first plane, between the projection of the end point where the gate portion is connected to the field plate portion and the projection of the end point where the bottom surface is connected to the first side surface, and the M0′ represents a distance, on another side of the first plane, between the projection of the end point where the gate portion is connected to the field plate portion and the projection of the end point where the bottom surface is connected to the first side surface; and the L0 represents a distance between the projection of the end point, on the side of the first plane, where the bottom surface is connected to the first side surface and the projection of the end point, on the another side of the first plane, where the bottom surface is connected to the first side surface.

12. The gate structure according to claim 11, wherein in either of the two parts, a distance relationship between the bottom surface of the gate portion and the end point where the gate portion is connected to the field plate portion is: M0≤D0, and the D0 represents a perpendicular distance between the bottom surface of the gate portion and an upper surface, close to the field plate portion, of the gate portion.

13. The gate structure according to claim 11, wherein in either of the two parts, the gate portion further comprises a second side surface, an end of the second side surface is connected to the first side surface, and another end of the second side surface is connected to the field plate portion,
wherein a position relationship between an end point where the second side surface is connected to the field plate portion and an end point where the first side surface is connected to the second side surface comprises:
on the plane where the bottom surface of the gate portion is located, a projection of the end point where the second side surface is connected to the field plate portion being located on a side, away from the first plane, of a projection of the end point where the first side surface is connected to the second side surface,
or, on the plane where the bottom surface of the gate portion is located, a projection of the end point where the second side surface is connected to the field plate portion being coincidence with a projection of the end point where the first side surface is connected to the second side surface.

14. The gate structure according to claim 11, wherein M0=M0′.

15. A semiconductor device, comprising:
a substrate;
a semiconductor layer formed on a side of the substrate;
a passivation layer formed on a side, away from the substrate, of the semiconductor layer; and
the gate structure according to claim 1, the gate structure being formed on a side, away from the substrate, of the passivation layer, and a field plate portion being located on a side, away from the semiconductor layer, of a gate portion.

16. The semiconductor device according to claim 15, further comprising a nucleating layer, a buffer layer, a channel layer and a barrier layer that are sequentially arranged in a direction away from the substrate,
wherein the channel layer and the barrier layer form a heterojunction together, and a two-dimensional electron gas layer is formed at the heterojunction;
the field plate portion comprises at least two field plate sub-portions, a position relationship between two adjacent field plate sub-portions and the two-dimensional electron gas layer is: L (X−1)<5.5*H (X−1) and LX<5.5*HX, wherein the X is an integer equal to or greater than 2;
in a direction from the gate portion to the field plate portion, the gate portion and the field plate portion are each divided into two parts by a first plane, and in either of the two parts, on a plane where a bottom surface of the gate portion is located, the L (X−1) represents a distance between a projection of a start end point on a lower surface of a lower field plate sub-portion and a projection of a tail end point on the lower surface of the lower field plate sub-portion, the LX represents a distance between a projection of a start end point on a lower surface of an upper field plate sub-portion and a projection of a tail end point on the lower surface of the upper field plate sub-portion, the H (X−1) represents a perpendicular distance between the lower surface of the lower field plate sub-portion and the two-dimensional electron gas layer, and the HX represents a perpendicular distance between the lower surface of the upper field plate sub-portion and the two-dimensional electron gas layer; and
in the two adjacent field plate sub-portions, a field plate sub-portion away from the gate portion is an upper field plate sub-portion, and a field plate sub-portion close to the gate portion is a lower field plate sub-portion; and in each of the two parts, an upper surface of one field plate sub-portion is a surface away from the gate portion, and a lower surface of one field plate sub-portion is a surface close to the gate portion; and on a surface, on a same side, of a same field plate sub-portion, a start end point is an end point, close to the first plane, of the surface of the field plate sub-portion, and a tail end point is an end point, away from the first plane, of the surface of the field plate sub-portion.

17. A preparation method for a semiconductor device, applied for preparing the semiconductor device according to claim 15, the preparation method comprising:
forming a semiconductor layer on a side of a substrate;
forming a passivation layer on a side, away from the substrate, of the semiconductor layer;
performing a first photoetch on the passivation layer using a first photoresist to etch the passivation layer, so as to form a first layer of an opening in the passivation layer, in a direction perpendicular to a direction from the substrate to the passivation layer, an opening size of the first photoresist before etching being L1+L1′+L0+M0+M0′, and an opening size of the first photoresist after etching being L1+L1′+L0+M0+M0′+M1+M1′, and in the direction from the substrate to the passivation layer, a size of the first layer of an opening being D1;
performing, based on the first layer of an opening, a second photoetch on the passivation layer using a second photoresist to etch the passivation layer, so as to form a second layer of an opening below the first layer of an opening in the passivation layer, in the direction perpendicular to the direction from the substrate to the passivation layer, an opening size of the second photoresist before etching being L0, and an opening size of the second photoresist after etching being L0+M0+M0′, and in the direction from the substrate to the passivation layer, a size of the second layer of an opening being D0, and the second layer of an opening exposing the semiconductor layer; and
depositing a gate structure, so as to form a gate portion and a field plate portion, the gate portion fully filling the second layer of an opening, and the field plate portion covering the gate portion and fully filling the first layer of an opening,
wherein in a direction from the gate portion to the field plate portion, the field plate portion comprises at least two field plate sub-portions, and the gate portion and the field plate portion are each divided into two parts by a first plane;
in either of the two parts, on a plane where a bottom surface of the gate portion is located, the M0 represents a distance, on a side of the first plane, between a projection of an end point where the gate portion is connected to a field plate sub-portion adjacent to the gate portion and a projection of an end point where the bottom surface of the gate portion is connected to a first side surface of the gate portion, and the M0′ represents a distance, on another side of the first plane, between a projection of an end point where the gate portion is connected to a field plate sub-portion adjacent to the gate portion and a projection of an end point where the bottom surface is connected to a first side surface of the gate portion; the M1 represents a distance, on the side of the first plane, between a projection of a tail end point on a lower surface of the field plate sub-portion adjacent to the gate portion and a projection of a start end point on a lower surface of a field plate sub-portion connected to the field plate sub-portion adjacent to the gate portion, and the M1′ represents a distance, on the another side of the first plane, between a projection of a tail end point on a lower surface of the field plate sub-portion adjacent to the gate portion and a projection of a start end point on a lower surface of a field plate sub-portion connected to the field plate sub-portion adjacent to the gate portion; the L1 represents a distance, on the side of the first plane, between a projection of a start end point on the lower surface of the field plate sub-portion adjacent to the gate portion and the projection of the tail end point on the lower surface of the field plate sub-portion adjacent to the gate portion, and the L1′ represents a distance, on the another side of the first plane, between a projection of a start end point on the lower surface of the field plate sub-portion adjacent to the gate portion and the projection of the tail end point on the lower surface of the field plate sub-portion adjacent to the gate portion; and the L0 represents a distance between the projection of the end point, on the side of the first plane, where the bottom surface is connected to the first side surface and the projection of the end point, on the another side of the first plane, where the bottom surface is connected to the first side surface; and
in each of the two parts, an upper surface of one field plate sub-portion is a surface away from the gate portion, and a lower surface of one field plate sub-portion is a surface close to the gate portion; and on a surface, on a same side, of a same field plate sub-portion, a start end point is an end point, close to the first plane, of the surface of the field plate sub-portion, and a tail end point is an end point, away from the first plane, of the surface of the field plate sub-portion.

18. A preparation method for a semiconductor device, applied for preparing the semiconductor device according to claim 15, the preparation method comprising:
forming a semiconductor layer on a side of a substrate;
forming a passivation layer on a side, away from the substrate, of the semiconductor layer;
performing a first photoetch on the passivation layer using a photoresist to etch the passivation layer, so as to form a first layer of an opening in the passivation layer, in a direction perpendicular to a direction from the substrate to the passivation layer, an opening size of the photoresist before etching being L0, and an opening size of the photoresist after etching being L0+M0+M0′, and in the direction from the substrate to the passivation layer, a size of the first layer of an opening being D0;
widening, by selective etching, the photoresist after etching, in the direction perpendicular to the direction from the substrate to the passivation layer, an opening size of the photoresist after widening being L1+L1′+L0+M0+M0′;
performing, based on the first layer of an opening, a second photoetch on the passivation layer using the photoresist after widening to etch the passivation layer, so as to descend the first layer of an opening in a direction towards the substrate integrally, thereby forming a second layer of an opening above the first layer of an opening in the passivation layer, in the direction perpendicular to the direction from the substrate to the passivation layer, an opening size of the photoresist after etching and widening being L1+L1′+L0+M0+M0′+M1+M1′, and in the direction from the substrate to the passivation layer, a size of the second layer of an opening being D1, and the first layer of an opening exposing the semiconductor layer; and
depositing a gate structure, so as to form a gate portion and a field plate portion, the gate portion fully filling the first layer of an opening, and the field plate portion covering the gate portion and fully filling the second layer of an opening,
wherein in a direction from the gate portion to the field plate portion, the field plate portion comprises at least two field plate sub-portions, and the gate portion and the field plate portion are each divided into two parts by a first plane;
in either of the two parts, on a plane where a bottom surface of the gate portion is located, the M0 represents a distance, on a side of the first plane, between a projection of an end point where the gate portion is connected to a field plate sub-portion adjacent to the gate portion and a projection of an end point where the bottom surface of the gate portion is connected to a first side surface of the gate portion, and the M0′ represents a distance, on another side of the first plane, between a projection of an end point where the gate portion is connected to a field plate sub-portion adjacent to the gate portion and a projection of an end point where the bottom surface is connected to a first side surface of the gate portion; the M1 represents a distance, on the side of the first plane, between a projection of a tail end point on a lower surface of the field plate sub-portion adjacent to the gate portion and a projection of a start end point on a lower surface of a field plate sub-portion connected to the field plate sub-portion adjacent to the gate portion, and the M1′ represents a distance, on the another side of the first plane, between a projection of a tail end point on a lower surface of the field plate sub-portion adjacent to the gate portion and a projection of a start end point on a lower surface of a field plate sub-portion connected to the field plate sub-portion adjacent to the gate portion; the L1 represents a distance, on the side of the first plane, between a projection of a start end point on the lower surface of the field plate sub-portion adjacent to the gate portion and the projection of the tail end point on the lower surface of the field plate sub-portion adjacent to the gate portion, and the L1′ represents a distance, on the another side of the first plane, between a projection of a start end point on the lower surface of the field plate sub-portion adjacent to the gate portion and the projection of the tail end point on the lower surface of the field plate sub-portion adjacent to the gate portion; and the L0 represents a distance between the projection of the end point, on the side of the first plane, where the bottom surface is connected to the first side surface and the projection of the end point, on the another side of the first plane, where the bottom surface is connected to the first side surface; and
in each of the two parts, an upper surface of one field plate sub-portion is a surface away from the gate portion, and a lower surface of one field plate sub-portion is a surface close to the gate portion; and on a surface, on a same side, of a same field plate sub-portion, a start end point is an end point, close to the first plane, of the surface of the field plate sub-portion, and a tail end point is an end point, away from the first plane, of the surface of the field plate sub-portion.
